(19) United States
(12) Patent Application Publication
(10) Pub. No.: US 2024/0096604 A1
(43) Pub. Date: Mar. 21, 2024

(54) SUBSTRATE PROCESSING APPARATUS, PLASMA GENERATION APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Yukinori ABURATANI, Toyama-shi (JP); Kaoru YAMAMOTO, Toyama-shi (JP)

(73) Assignee: Kokusai Electric Corporation, Tokyo (JP)

(21) Appl. No.: 18/471,002

(22) Filed: Sep. 20, 2023

(30) Foreign Application Priority Data
Sep. 21, 2022 (JP) 2022-150572
Jun. 29, 2023 (JP) 2023-107577

(51) Int. Cl. H01J 37/32

(52) U.S. Cl. CPC H01J 37/32568; H01J 37/32091; H01J 37/3244; H01J 37/32541; H01J 37/32743; H01J 37/32788

(57) ABSTRACT

There is provided a technique that includes: a process chamber configured to process a plurality of substrates; and a plasma generator configured to generate plasma in the process chamber, the plasma generator including a first electrode part configured to extend from a lower side to an intermediate side of the process chamber, and a second electrode part configured to extend from an upper side to the intermediate side of the process chamber.

### CROSS-REFERENCE TO RELATED APPLICATIONS

This application is based upon and claims the benefit of priorities from Japanese Patent Application No. 2022-150572, filed on Sep. 21, 2022, and Japanese Patent Application No. 2023-107577, filed on Jun. 29, 2023, the entire contents of which are incorporated herein by reference.

### TECHNICAL FIELD

The present disclosure relates to a substrate processing apparatus, a plasma generation apparatus, a method of processing a substrate, a method of manufacturing a semiconductor device, and a recording medium.

### BACKGROUND

As a process of manufacturing a semiconductor device, substrate processing may be performed in which a substrate is loaded into a process chamber of a substrate processing apparatus, a precursor gas and a reaction gas are supplied into the process chamber to form various films such as an insulating film, a semiconductor film, a conductor film, and the like on the substrate, and the various films are removed.

In mass-produced devices in which fine patterns are formed, a temperature is sometimes lowered such that diffusion of impurities is suppressed and materials with a low heat resistance, such as an organic material and the like, may be used.

To satisfy such a technical demand, substrate processing is generally performed by using plasma. However, it may be difficult to uniformly process the film formed on the substrate.

### SUMMARY

Some embodiments of the present disclosure provide a technique capable of uniformly processing a film formed on a substrate.

According to some embodiments of the present disclosure, there is provided a technique that includes: a process chamber configured to process a plurality of substrates; and a plasma generator configured to generate plasma in the process chamber, the plasma generator including a first electrode part configured to extend from a lower side to an intermediate side of the process chamber, and a second electrode part configured to extend from an upper side to the intermediate side of the process chamber.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus appropriately used in embodiments of the present disclosure, in which a portion of the process furnace is shown in a vertical cross section.

FIG. 2 is a cross-sectional view taken along line A-A in the substrate processing apparatus shown in FIG. 1.

FIG. 3A is a perspective view showing a state in which an electrode according to embodiments of the present disclosure is installed on a quartz cover, and FIG. 3B is a diagram showing a positional relationship among a heater, a quartz cover, electrodes, protrusions configured to fix the electrodes, and a reaction tube according to embodiments of the present disclosure.

FIG. 4A is a perspective view showing a state in which an electrode according to a first modification of embodiments of the present disclosure is installed on a quartz cover, and FIG. 4B is a diagram showing a positional relationship between a heater, a quartz cover, electrodes, protrusions configured to fix the electrodes, and a reaction tube according to the first modification of embodiments of the present disclosure.

FIG. 5A is a front view of an electrode according to embodiments of the present disclosure, and FIG. 5B is a diagram illustrating how to fix the electrode to the quartz cover.

FIG. 6A is a front view showing an example of a positional relationship between an electrode unit and a reaction tube according to embodiments of the present disclosure, FIG. 6B is a top view showing an example of a positional relationship between an electrode unit and a reaction tube according to embodiments of the present disclosure, and FIG. 6C is a bottom view showing an example of a positional relationship between an electrode unit and a reaction tube according to embodiments of the present disclosure.

FIG. 7A is a front view showing an example of a positional relationship between an electrode unit and a reaction tube according to the first modification of embodiments of the present disclosure, FIG. 7B is a top view showing an example of a positional relationship between an electrode unit and a reaction tube according to the first modification of embodiments of the present disclosure, and FIG. 7C is a bottom view showing an example of a positional relationship between an electrode unit and a reaction tube according to the first modification of embodiments of the present disclosure.

FIG. 8A is a front view showing another example of a positional relationship between an electrode unit and a reaction tube according to embodiments of the present disclosure, FIG. 8B is a cross-sectional top view taken along line A-A in FIG. 8A, and FIG. 8C is a cross-sectional top view taken along line B-B in FIG. 8A.

FIG. 9A is a front view showing another example of a positional relationship between an electrode unit and a reaction tube according to the first modification of embodiments of the present disclosure, FIG. 9B is a cross-sectional top view taken along line A-A in FIG. 9A, and FIG. 9C is a cross-sectional top view taken along line B-B in FIG. 9A.

FIG. 10A is a front view showing another example of a positional relationship between an electrode unit and a reaction tube according to a second modification of embodiments of the present disclosure, FIG. 10B is a cross-sectional top view taken along line A-A in FIG. 10A, and FIG. 10C is a cross-sectional top view taken along line B-B in FIG. 10A.

FIG. 11 is a schematic configuration diagram of a controller of the substrate processing apparatus shown in FIG. 1, and is a block diagram showing an example of a control system of the controller.

FIG. 12 is a flowchart showing an example of a substrate processing process in which the substrate processing apparatus shown in FIG. 1 is used.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to unnecessarily obscure aspects of the various embodiments.

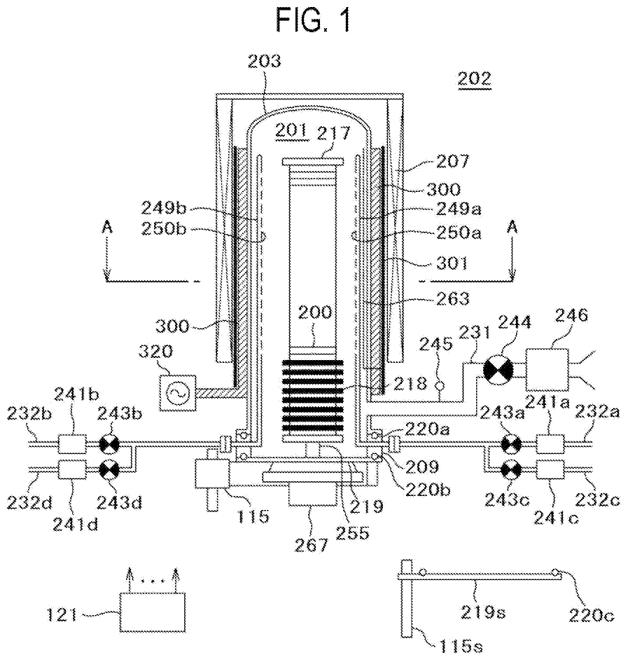

Hereinafter, embodiments of the present disclosure will be described with reference to FIGS. 1 to FIG. 11. Throughout the drawings, the same or corresponding configurations are denoted by the same or corresponding reference numerals, and duplicated descriptions thereof are omitted. The drawings used in the following description are schematic, and dimensional relationships of the respective components, ratios of the respective components, and the like shown in the drawings may not match actual ones. Moreover, dimensional relationships of the respective components, ratios of the respective components, and the like may not match among plural drawings.

### (1) Configuration of Substrate Processing Apparatus

### (Heater)

As shown in FIG. 1, a process furnace 202 of a vertical substrate processing apparatus includes a heater 207 as a heating apparatus (heating equipment). The heater 207 is formed in a cylindrical shape and is vertically installed by being supported by a heater base (not shown) as a holding plate. Further, the heater 207 is installed outside an electrode fixture 301, which will be described later. The heater 207 also functions as an activator (exciter) configured to thermally activate (excite) a gas, as will be described later.

### (Process Chamber)

An electrode fixture 301, which will be described later, is arranged inside the heater 207, and an electrode 300 of a plasma generator, which will be described later, is arranged inside the electrode fixture 301. Furthermore, a reaction tube 203 is arranged concentrically with the heater 207 inside the electrode 300. The reaction tube 203 is made of, for example, a heat-resistant material such as quartz (SiO₂) or silicon carbide (SiC), and is formed in a cylindrical shape with a closed upper end and an open lower end. A manifold 209 is arranged concentrically with the reaction tube 203 below the reaction tube 203. The manifold 209 is made of, for example, metal such as stainless steel (SUS), and is formed in a cylindrical shape with open upper and lower ends. The upper end of the manifold 209 is engaged with the lower end of the reaction tube 203 and is configured to support the reaction tube 203. An 0-ring 220a as a seal is provided between the manifold 209 and the reaction tube 203. By allowing the manifold 209 to be supported on the heater base, the reaction tube 203 is vertically installed. A process container (reaction container) mainly includes the reaction tube 203 and the manifold 209. A process chamber 201 is formed in a cylindrical hollow area of the process container. The process chamber 201 is configured to be capable of accommodating a plurality of wafers 200 as substrates. The reaction tube 203 forms the process chamber 201 in which the wafers 200 are processed. The process container is not limited to the above-described configuration, and the reaction tube 203 may be called a process container (reaction container).

### (Gas Supplier)

Nozzles 249a and 249b are installed in the process chamber 201 so as to penetrate a side wall of the manifold 209. Gas supply pipes 232a and 232b are connected to the nozzles 249a and 249b, respectively. In this manner, two nozzles 249a and 249b and two gas supply pipes 232a and 232b are installed in the process container, which makes it possible to supply a plurality of types of gases into the process chamber 201. When the reaction tube 203 is used as the process container, the nozzles 249a and 249b may be installed so as to penetrate the side wall of the reaction tube 203.

At the gas supply pipes 232a and 232b, mass flow controllers (MFC) 241a and 241b as flow rate controllers (flow rate control parts) and valves 243a and 243b as opening/closing valves are installed sequentially from the upstream side of a gas flow, respectively. Gas supply pipes 232c and 232d configured to supply an inert gas are connected to the gas supply pipes 232a and 232b on the downstream side of the valves 243a and 243b, respectively. At the gas supply pipes 232c and 232d, MFCs 241c and 241d and valves 243c and 243d are installed sequentially from the upstream side of the gas flow, respectively.

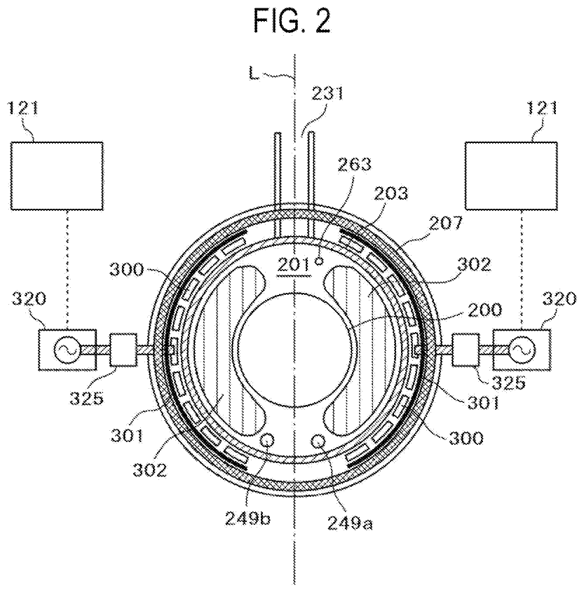

As shown in FIG. 2, the nozzles 249a and 249b are respectively arranged in an annular space between the inner wall of the reaction tube 203 and the wafers 200 in a plane view and are installed to extend upward in a stacking direction of the wafers 200 from a lower side to an upper side of the inner wall of the reaction tube 203. That is, the nozzles 249a and 249b are installed on the lateral side of the end (peripheral edge) of each wafer 200 loaded into the process chamber 201 so as to be perpendicular to the surface (flat surface) of the wafer 200. Gas supply holes 250a and 250b configured to supply gases are formed on the side surfaces of the nozzles 249a and 249b, respectively. The gas supply holes 250a are opened to face the center of the reaction tube 203 and are configured to be capable of supplying a gas toward the wafer 200. The gas supply holes 250a and 250b are respectively formed from the lower side to the upper side of the reaction tube 203.

As described above, in the embodiments of the present disclosure, gases are transferred via the nozzles 249a and 249b disposed in a vertically-elongated space formed in an annular shape in the plane view, i.e., a cylindrical space, which is defined by the inner wall of the side wall of the reaction tube 203 and the ends (peripheral edges) of the plurality of wafers 200 arranged in the reaction tube 203. Then, the gases are ejected into the reaction tube 203 for the first time near the wafers 200 from the gas supply holes 250a and 250b formed in the nozzles 249a and 249b, respectively. A main gas flow in the reaction tube 203 is in a direction parallel to the surfaces of the wafers 200, i.e., in a horizontal direction. According to such a configuration, the gas may be uniformly supplied to each wafer 200, and uniformity of a thickness of a film formed on each wafer 200 may be improved. The gas flowing on the surface of the wafer 200, i.e., residual gas after reaction, flows toward an exhaust port, i.e., an exhaust pipe 231, which will be described later. However, a direction of flow of the residual gas is appropriately specified depending on a position of the exhaust port, and is not limited to a vertical direction.

A precursor gas is supplied into the process chamber 201 from the gas supply pipe 232a via the MFC 241a, the valve 243a, and the nozzle 249a.

A reaction gas is supplied into the process chamber 201 from the gas supply pipe 232b via the MFC 241b, the valve 243b, and the nozzle 249b.

An inert gas is supplied into the process chamber 201 from the gas supply pipes 232c and 232d via the MFCs 241c and 241d, the valves 243c and 243d, and the nozzles 249a and 249b, respectively.

A precursor gas supply system mainly includes the gas supply pipe 232a, the MFC 241a, and the valve 243a. A reaction gas supply system mainly includes the gas supply pipe 232b, the MFC 241b, and the valve 243b. An inert gas supply system mainly includes the gas supply pipes 232c and 232d, the MFCs 241c and 241d, and the valves 243c and 243d. The precursor gas supply system, the reaction gas supply system, and the inert gas supply system are also simply referred to as a gas supply system (gas supplier). The precursor gas and the reaction gas are also referred to as a processing gas.

### (Substrate Support)

As shown in FIG. 1, a boat 217 serving as a substrate support is configured to support (hold) a plurality of wafers 200, for example, 25 to 200 wafers 200, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat-resistant material such as quartz or SiC. At the bottom of the boat 217, heat insulating plates 218 made of, for example, a heat-resistant material such as quartz or SiC are supported in multiple stages. This configuration makes it difficult for heat to be transferred from the heater 207 toward the seal cap 219. However, the embodiments of the present disclosure is not limited to such a form. For example, instead of installing the heat insulating plates 218 at the bottom of the boat 217, a heat insulating cylinder made of a heat-resistant material such as quartz or SiC may be installed.

### (Plasma Generator)

Next, a plasma generator will be described with reference to FIGS. 1, 2, 3A, 3B, 4A, 4B, 5A, 5B, 6A to 6C, 7A to 7C, 8A to 8C, and 9A to 9C.

Outside the reaction tube (processing container) 203, i.e., outside the process chamber 201, an electrode 300 configured to generate a plasma is installed parallel to the wall surface of the reaction tube (process container) 203. By applying electric power to the electrode 300, the gas inside the reaction tube (process container) 203, i.e., inside the process chamber 201 may be converted into plasma and excited. That is, the gas may be excited into a plasma state. Hereinafter, the act of exciting a gas into a plasma state is also simply referred to as plasma excitation. The electrode 300 is configured to, when electric power, that is, high-frequency power (RF power) is applied to the electrode 300, generate a capacitively coupled plasma (CCP) in the reaction tube (process container) 203, i.e., in the process chamber 201.

Specifically, as shown in FIG. 2, an electrode 300 and an electrode fixture 301 configured to fix the electrode 300 are arranged between the heater 207 and the reaction tube 203. The electrode fixture 301 is arranged inside the heater 207, the electrode 300 is arranged inside the electrode fixture 301, and the reaction tube 203 is arranged inside the electrode 300. That is, since the electrode 300 and the electrode fixture 301 are installed outside the process chamber 201, they are not exposed to the processing gas. Since the electrode 300 and the electrode fixture 301 are installed inside the heater 207, the heater 207 does not become a barrier to the high-frequency power from the electrode 300.

As shown in FIGS. 1 and 2, the electrode 300 and the electrode fixture 301 are installed in an annular space between the inner wall of the heater 207 and the outer wall of the reaction tube 203 in a plane view, and are installed so as to extend in an arrangement direction of the wafers 200 from the lower side to the upper side of the outer wall of the reaction tube 203. The electrode 300 is installed parallel to the nozzles 249a and 249b. The electrodes 300 and the electrode fixture 301 are arranged concentrically with the reaction tube 203 and the heater 207 in the plane view and disposed so as not to be in contact with the reaction tube 203 and the heater 207. The electrode fixture 301 is made of an insulating material (insulator) and installed to at least partially cover the electrode 300 and the reaction tube 203. In view of this, the electrode fixture 301 may also be called a cover (cover, quartz cover, insulating wall, or insulating plate) or a cover of an arc-shaped cross section (a body of an arc-shaped cross section or a wall of an arc-shaped cross section). Thus, the electrode fixture 301 may reduce an electromagnetic wave radiation from the electrode 300 to the outside of the substrate processing apparatus.

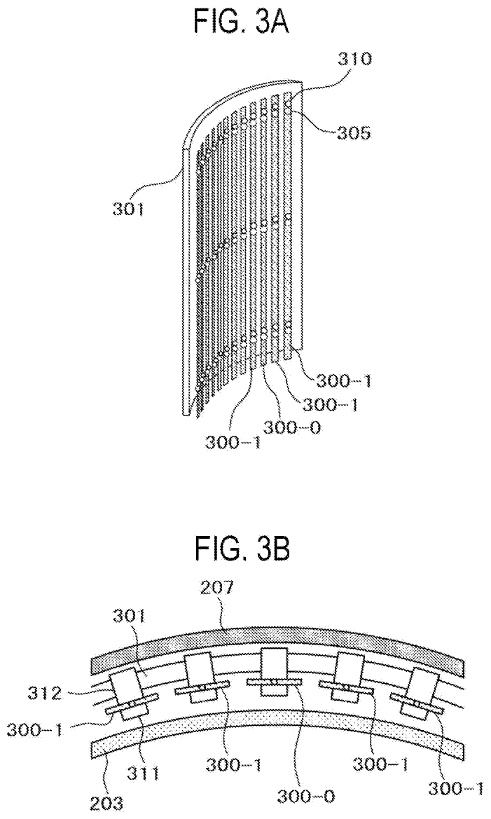

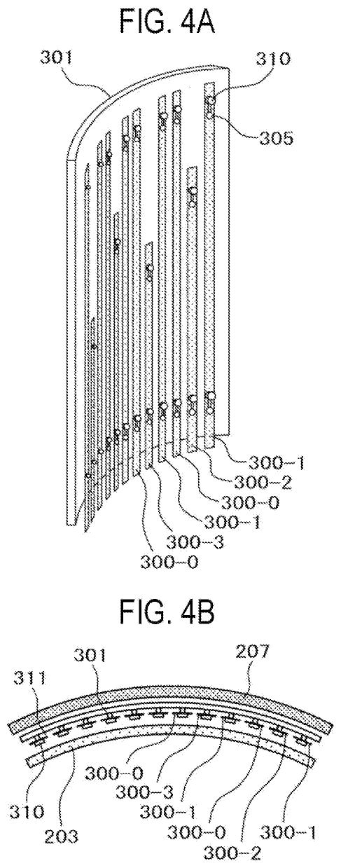

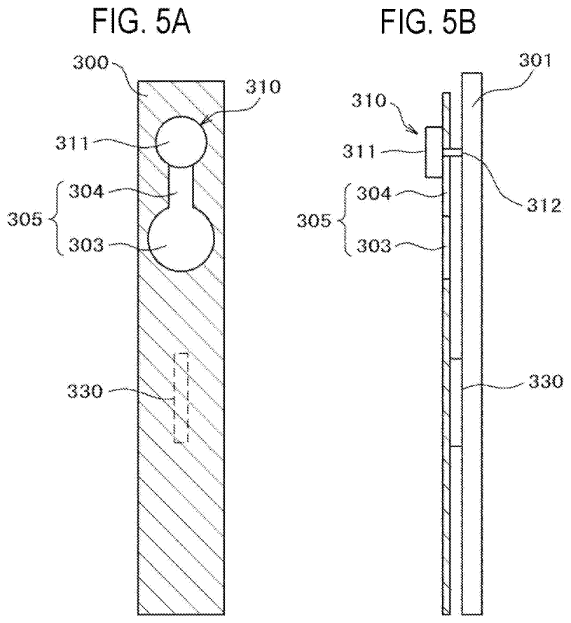

As shown in FIG. 2, a plurality of electrodes 300 are provided. These electrodes 300 are installed to be fixed on the inner wall of the electrode fixture 301. Specifically, as shown in FIGS. 5A and 5B, the inner wall surface of the electrode fixture 301 is provided with a protrusions (hooks) 310 on which the electrodes 300 may be hooked. The electrodes 300 are provided with openings 305 as through-holes through which the protrusions 310 may be inserted. The electrodes 300 may be fixed to the electrode fixture 301 by being hooked on the protrusions 310 installed on the inner wall surface of the electrode fixture 301 via the openings 305. FIG. 3A shows an example in which three openings 305 are formed for one electrode 300 and the one electrode 300 is fixed by being hooked on three protrusions 310. That is, there is shown an example in which one electrode is fixed at three points. FIG. 4A shows an example in which two openings 305 are formed for one electrode 300, and the one electrode 300 is fixed by being hooked on two protrusions 310. That is, there is shown an example in which one electrode is fixed at two points. FIG. 2 shows two electrode units in which nine electrodes 300 are fixed to one electrode fixture 301. In addition, FIG. 2 shows an example of an electrode unit in which six electrodes 300-1 and three electrodes 300-0 are fixed to one electrode fixture 301.

The electrodes 300 (first-type electrode 300-1, second-type electrode 300-2, third type electrode 300-3, and zero-type electrode 300-0) are made of an oxidation-resistant material such as nickel (Ni) or the like. The electrodes 300 may be made of a metal material such as stainless steel (SUS), aluminum (Al), copper (Cu), or the like. However, by making the electrodes 300 of an oxidation-resistant material such as Ni or the like, it is possible to suppress deterioration of electrical conductivity and suppress a decrease in plasma generation efficiency. Furthermore, the electrodes 300 may also be made of a Ni alloy material to which Al is added. In this case, an aluminum oxide film (AlO film), which is an oxide film of high heat resistance and high corrosion resistance, may be formed on the outermost surfaces of the electrodes 300. The AlO film formed on the outermost surfaces of the electrodes 300 acts as a protective film (blocking film, or barrier film), and may suppress progress of deterioration inside the electrodes 300. This makes it possible to further suppress reduction in plasma generation efficiency due to reduction in electrical conductivity of the electrodes 300. The electrode fixture 301 is made of an insulating material (insulator), for example, a heat-resistant material such as quartz or SiC. The material of the electrode fixture 301 may be the same as the material of the reaction tube 203.

As shown in FIGS. 3A and 3B, the electrodes 300 include the first-type electrodes 300-1 and the zero-type electrodes 300-0. As shown in FIGS. 4A and 4B, the electrodes 300 include the first-type electrodes 300-1, the second-type electrodes 300-2, the third type electrodes 300-3, and the zero-type electrodes 300-0. The first-type electrodes 300-1, the second-type electrodes 300-2, and the third type electrodes 300-3 are connected to a high-frequency power source (RF power source) 320 via a matcher 325, and an arbitrary potential is applied thereto. The zero-type electrodes 300-0 are grounded to be at a reference potential (0 V). The first-type electrodes 300-1, the second-type electrodes 300-2, and the third type electrodes 300-3 are also referred to as Hot electrodes, HOT electrodes, or first electrodes. Further, the zero-type electrodes 300-0 are also called ground electrodes, GND electrodes, or second electrodes. The first-type electrodes 300-1, the second-type electrodes 300-2, the third type electrodes 300-3, and the zero-type electrodes 300-0 are formed in a plate-like (flat plate-like) shape in a front view. FIG. 3A shows an example in which eight first-type electrodes 300-1 and four zero-type electrodes 300-0 are installed. FIGS. 4A and 4B show an example in which a plurality of third type electrodes 300-3 are further installed and in which four first-type electrodes 300-1, two second-type electrodes 300-2, two third type electrodes 300-3, and four zero-type electrodes 300-0 are installed. Since an arbitrary potential is applied to the first electrodes and a reference potential is applied to the second electrodes, arbitrary RF power is applied to between the first electrodes and the second electrodes. This makes it possible to control the amount of plasma generated. By providing a plurality of first electrodes, it is possible to expand the plasma generation region.

By applying the RF power to between the first-type electrodes 300-1 and the zero-type electrodes 300-0 from the RF power source 320 via the matcher 325, plasma is generated in the regions between the first-type electrodes 300-1 and the zero-type electrodes 300-0. Similarly, by applying the RF power to between the second-type electrodes 300-2 and the zero-type electrodes 300-0, plasma is generated in the regions between the second-type electrodes 300-2 and the zero-type electrodes 300-0. Similarly, by applying the RF power to between the third type electrodes 300-3 and the zero-type electrodes 300-0, plasma is generated in the regions between the third type electrodes 300-3 and the zero-type electrodes 300-0. These regions are also called plasma generation regions.

In addition, as shown in FIG. 1, the electrodes 300 are arranged in a direction perpendicular to the process container (in the vertical direction, or the direction in which the substrates are stacked). Further, as shown in FIGS. 2, 3A, 3B, 4A and 4B, the electrodes 300 are arranged in an arc shape in the plane view and at regular intervals, that is, in such a manner that distances (gaps) between the adjacent electrodes 300 (the first-type electrodes 300-1, the second-type electrodes 300-2, the third type electrodes 300-3, and the zero-type electrode 300-0) are equal. As shown in FIGS. 2, 3B, and 4B, the electrodes 300 are arranged between the reaction tube 203 and the heater 207 substantially in an arc shape in the plane view along the outer wall of the reaction tube 203. The electrodes 300 are fixed to the inner wall surface of the electrode fixture 301 formed in an arc shape with a central angle of 30 degrees or more and 240 degrees or less, for example. In addition, as described above, the electrodes 300 are installed parallel to the nozzles 249a and 249b.

As shown in FIG. 2, the electrode units may be arranged at positions avoiding the nozzles 249a and 249b and the exhaust pipe 231. FIG. 2 shows an example in which two electrode units are arranged to face each other across the center of the wafer 200 (the reaction tube 203) while avoiding the nozzles 249a and 249b and the exhaust pipe 231. Further, FIG. 2 shows an example in which two electrode units are arranged in a line symmetric relationship, that is, symmetrically with respect to the straight line L as an axis of symmetry in the plane view. By arranging the electrode units in this way, the nozzles 249a and 249b, the temperature sensor 263, and the exhaust pipe 231 may be arranged outside the plasma generation region in the process chamber 201. This makes it possible to suppress plasma damage to these members, wear and tear of these members, and generation of particles from these members. In the present disclosure, in a case where the electrodes may be described without being distinguished from one another specifically, the electrodes will be described as electrodes 300.

Electrical power at a high frequency of, for example, 25 MHz or more and 35 MHz or less, more specifically, 27.12 MHz is inputted to the electrodes 300 from the high-frequency power source 320 via a matcher 325, thereby generating plasma (active species) 302 in the reaction tube 203. The plasma generated in this manner makes it possible to supply the plasma 302 for substrate processing to the surface of the wafer 200 from the surroundings of the wafer 200. The electric power is supplied from the lower sides (lower ends) of the electrodes 300.

A plasma generator (plasma exciter, plasma activator, or plasma generation apparatus) configured to excite (activate) a gas into a plasma state mainly includes the electrodes 300, i.e., the first electrodes (the first-type electrodes 300-1, the second-type electrodes 300-2, and the third type electrodes 300-3) and the second electrodes (the zero-type electrodes 300-0). At least one selected from the group of the electrode fixture 301, the matcher 325, and the RF power supply 320 may be included in the plasma generator.

In addition, as shown in FIG. 5A, the electrode 300 includes an opening 305 formed by a circular notch 303 through which a protrusion head 311 (to be described later) passes and a slide notch 304 along which a protrusion shaft 312 slides.

The electrode 300 may be formed with a thickness within a range of 0.1 mm or more and 1 mm or less and a width within a range of 5 mm or more and 30 mm or less such that a strength of the electrode 300 is sufficient and an efficiency in heating the wafer by a heat source is not lowered significantly. Further, the electrode 300 may include a bending structure as a deformation suppressor to prevent deformation due to the heating by the heater 207. In this case, since the electrode 300 is arranged between the reaction tube 203 and the heater 207, an appropriate bending angle is 90 to 175 degrees in view of space restrictions. A film may be formed on the surface of the electrode by thermal oxidation, and thermal stress may cause the film to be peeled off, generating particles. Therefore, the electrode should not be bent too much.

In the vertical substrate processing apparatus, for example, the frequency of the high-frequency power source 320 is set to 27.12 MHz, and the electrodes 300 with a length of 1650 mm and a thickness of 1 mm are used to generate CCP mode plasma.

As shown in FIGS. 3A and 3B, eight first-type electrodes 300-1 and four zero-type electrodes 300-0 are arranged on the outer wall of the tube-shaped reaction tube 203 in the order of the first-type electrode 300-1, the first-type electrode 300-1, the zero-type electrode 300-0, the first-type electrode 300-1, the first-type electrode 300-1, and so forth. In this case, the first-type electrode 300-1 is formed with, for example, a width of 10 mm and a height of 1650 mm. The zero-type electrode 300-0 is formed with, for example, a width of 10 mm and a height of 1650 mm. An electrode pitch (center-to-center distance) is 20 mm. That is, the electrodes 300 are arranged such that two first-type electrodes 300-1 are consecutively arranged, and one zero-type electrode 300-0 is interposed between two sets of consecutively-arranged first-type electrodes 300-1. Further, the lengths of the first electrodes (first-type electrodes 300-1) are equal, and the lengths of the first electrodes (first-type electrodes 300-1) are equal to the lengths of the second electrodes (the zero-type electrodes 300-0).

As shown in FIGS. 4A and 4B, on the outer wall of the tube-shaped reaction tube 203, four first-type electrodes 300-1, two second-type electrodes 300-2, two third-type electrodes 300-3, and four zero-type electrodes 300-0 are alternately arranged in the order of the first-type electrode 300-1, the second-type electrode 300-2, the zero-type electrode 300-0, the first-type electrode 300-1, the third-type electrode 300-3, the zero-type electrode 300-0, the first-type electrode 300-1, the second-type electrode 300- 2, the zero-type electrode 300-0, and so forth. In this case, the first-type electrode 300-1 is formed with, for example, a width of 12.5 mm and a height of 1650 mm. The second-type electrode 300-2 is formed with, for example, a width of 12.5 mm and a height of 1350 mm. The third-type electrode 300-3 is formed with, for example, a width of 12.5 mm and a height of 1050 mm. The zero-type electrode 300-0 is formed with, for example, a width of 12.5 mm and a height of 1650 mm. For example, a gap between the first-type electrode 300-1 and the second-type electrode 300-2, a gap between the second-type electrode 300-2 and the zero-type electrode 300-0, a gap between the zero-type electrode 300-0 and the first-type electrode 300-1, a gap between the first-type electrode 300-1 and the third-type electrode 300-3, and a gap between the third-type electrode 300-3 and the zero-type electrode 300-0 are 7.5 mm.

In FIGS. 4A and 4B, as for upper end positions of the electrodes 300, the first-type electrode 300-1 is flush with or lower than the zero-type electrode 300-0. Further, the second-type electrode 300-2 and the third-type electrode 300-3 are lower than both the first-type electrode 300-1 and the zero-type electrode 300-0. The third-type electrode 300-3 is lower than the second-type electrode 300-2. That is, the lengths of the first electrodes are different. In addition, the length of the first electrode (first-type electrode 300-1) with a longer length among the first electrodes is the same as that of the second electrode (zero-type electrode 300-0). Since a reflection coefficient is changed by regulating a length of a tip of the electrode 300, a voltage distribution of a standing wave in the wafer region may be shifted downward by changing a phase difference between a traveling wave and a reflected wave. As a result, it is possible to improve unevenness of the voltage distribution, thereby securing a density distribution of the plasma 302 with good uniformity, and improving uniformity of a film thickness and a film quality between the wafers 200.

In this case, a pressure inside the process furnace during substrate processing may be controlled to fall within a range of 10 Pa or more and 300 Pa or less. This is because when the pressure inside the process furnace is lower than 10 Pa, a mean free path of a gas molecule becomes longer than a Debye length of the plasma, and the plasma that directly hits a furnace wall becomes conspicuous, which makes it difficult to suppress the generation of particles. In addition, when the pressure inside the process furnace is higher than 300 Pa, the plasma generation efficiency is saturated. Therefore, even though the reaction gas is supplied, the amount of plasma generated is not changed, the mean free path of the gas molecule may be shortened while the reaction gas being wasted. Thus, an efficiency in transporting plasma active species to the wafer may deteriorate.

### (Electrode Fixing Jig)

Next, the electrode fixture 301 as an electrode fixing jig configured to fix the electrodes 300 will be described with reference to FIGS. 3A, 3B, 5A, and 5B. As shown in FIGS. 3A, 3B, 5A, and 5B, the electrodes 300 are fixed by hooking the openings 305 on the protrusions 310 formed on the inner wall surface of the electrode fixture 301 as an electrode fixing jig formed in a curved shape, and sliding the electrodes 300. The electrodes 300 are unitized (as hook-type electrode units) so as to be integrated with the electrode fixture 301, and are installed on the outer circumference of the reaction tube 203. Quartz and nickel alloy are used as materials for the electrode fixture 301 and the electrodes 300, respectively.

The electrode fixture 301 may be formed with a thickness of 1 mm or more and 5 mm or less such that a strength of the electrode fixture 301 is sufficient and an efficiency in heating the wafer by the heater 207 is not lowered significantly. In a case where the thickness of the electrode fixture 301 is less than 1 mm, it will be impossible to obtain a predetermined strength against own weight of the electrode fixture 301 and a temperature change. In a case where the thickness of the electrode fixture 301 is greater than 5 mm, the electrode fixture 301 may absorb heat energy radiated from the heater 207, making it impossible to properly heat-treat the wafer 200.

Further, the electrode fixture 301 includes a plurality of protrusions 310 as rivet-shaped fixing portions arranged on the inner wall surface on the side of the reaction tube so as to fix the electrodes 300. The protrusion 310 includes a protrusion head 311 and a protrusion shaft 312. A maximum width of the protrusion head 311 is smaller than a diameter of the circular notch 303 of the opening 305 of the electrode 300. Further, a maximum width of the protrusion shaft 312 is smaller than a width of a slide notch 304. The opening 305 of the electrode 300 is shaped like a keyhole. The slide notch 304 may guide the protrusion shaft 312 during sliding, and the protrusion head 311 is formed such that the protrusion shaft 312 is not removed from the slide notch 304. That is, it may be said that the electrode fixing jig includes a fixing portion including the protrusion head 311 which is a tip configured to prevent the electrode 300 from being removed from the protrusion shaft 312 as a columnar portion on which the electrode 300 is hooked. It is apparent that as long as the electrode 300 may be hooked on the electrode fixture 301, the shapes of the opening 305 and the protrusion head 311 described above are not limited to the shapes shown in FIGS. 3A, 3B, 5A, and 5B. For example, the protrusion head 311 may be formed in a convex shape like a hammer or a thorn.

To maintain a constant distance between the electrode fixture 301 or the reaction tube 203 and the electrode 300, the electrode fixture 301 or the electrode 300 may include an elastic body such as a spacer or a spring therebetween. The elastic body may be formed to be integrated with the electrode fixture 301 or the electrode 300. In the embodiments of the present disclosure, a spacer 330 as shown in FIG. 5B is integrated with the electrode fixture 301. It is effective to provide a plurality of spacers 330 for one electrode when the electrode 300 is fixed to the electrode fixture 301 while keeping the constant distance therebetween.

To obtain a high substrate processing capability at a substrate temperature of 500 degrees C. or less, an occupancy of the electrode fixture 301 may be set such that the electrode fixture 301 is formed substantially in an arc shape with a central angle of 30 degrees or more and 240 degrees or less. Further, to prevent generation of particles, the electrode fixture 301 may be arranged to avoid the exhaust pipe 231 as an exhaust port, the nozzles 249a and 249b, and the like. That is, the electrode fixture 301 is arranged on the outer periphery of the reaction tube 203 other than positions where the nozzles 249a and 249b as the gas suppliers installed in the reaction tube 203 and the exhaust pipe 231 as the gas exhauster are installed. In the embodiments of the present disclosure, two electrode fixtures 301 with a central angle of 110 degrees are installed symmetrically.

### (Spacer)

Next, FIGS. 5A and 5B show a spacer 330 configured to fix the electrode 300 at a certain distance with respect to the electrode fixture 301 which is an electrode fixing jig and the outer wall of the reaction tube 203. For example, the spacer 330 is made of a cylindrical quartz material and integrated with the electrode fixture 301. When the spacer 330 comes into contact with the electrode 300, the electrode 300 is fixed to the electrode fixture 301. As long as the electrode 300 may be fixed at a certain distance with respect to the electrode fixture 301 and the reaction tube 203, the spacer 330 may be formed in any shape. Further, the spacer 330 may be integrated with either the electrode 300 or the electrode fixture 301. For example, the spacer 330 may be a semi-cylindrical quartz material integrated with the electrode fixture 301 to fix the electrode 300. Alternatively, the spacer 330 may be made of a metal plate such as a stainless steel (SUS) plate or the like and may be integrated with the electrode 300 to fix the electrode 300. In any case, since the protrusion 310 and the spacer are provided, it becomes easy to position the electrode 300. Further, when the electrode 300 deteriorates, it is possible to replace the electrode 300 alone, resulting in cost reduction. The spacer 330 may be included in the electrode unit described above.

### (Arrangement of Electrode Unit)

To ensure high productivity, the electrode 300 may be lengthened. However, due to the lengthening of the electrodes, there may be concern about variation in distribution of plasma intensity (e.g., space potential) (for example, difference in the space potential between the tip and the base of the electrode) and influence of standing waves. In the vertical direction of the electrode 300, due to influence of biased voltage distribution of the standing waves (cosine curve) formed by superposition of the traveling waves and the reflected waves, bias in the density distribution of the plasma 302 also appears. Therefore, non-uniformity in film thickness and film quality that correlate with the density distribution of the plasma 302 appear among the wafers 200.

As an approach to resolve the aforementioned issue, the electrode units are divided and arranged in the longitudinal direction (vertical direction). By using this method, it is possible to improve the bias in the voltage distribution, secure the density distribution of the plasma 302 with good uniformity, and improve uniformity of the film thickness and the film quality among the wafers 200.

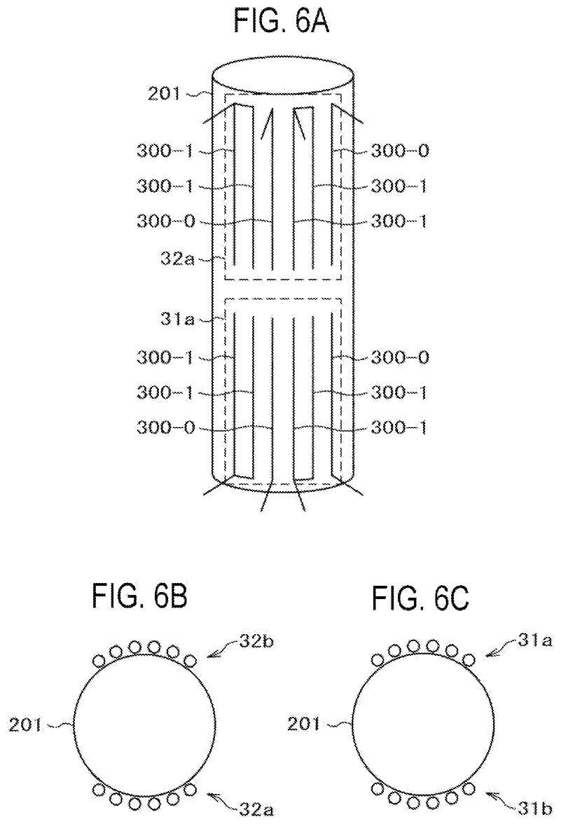

For example, as shown in FIGS. 6A to 6C, the electrode unit includes two first electrode parts 31a and 31b and two second electrode parts 32a and 32b. Here, the first electrode parts 31a and 31b and the second electrode parts 32a and 32b may be referred to as first electrode areas 31a and 31b and second electrode areas 32a and 32b, respectively. The first electrodes (first-type electrodes 300-1) and the second electrodes (zero-type electrodes 300-0) are arranged in the first electrode areas 31a and 31b respectively. Similarly, the first electrodes (first-type electrodes 300-1) and the second electrodes (zero-type electrodes 300-0) are also arranged in the second electrode areas 32a and 32b respectively. Additionally, each of the first electrode parts 31a and 31b may also be referred to as a group or a set of the first electrodes (first-type electrodes 300-1) and the second electrodes (zero-type electrodes 300-0). Similarly, each of the second electrode parts 32a and 32b may also be referred to as a group or a set of the first electrodes (first-type electrodes 300-1) and the second electrodes (zero-type electrodes 300-0). The first electrode parts 31a and 31b are configured to extend from the lower side to the intermediate side of the process chamber 201. The second electrode parts 32a and 32b are configured to extend from the upper side to the intermediate side of the process chamber 201. At the intermediate side of the process chamber 201, a gap exists between the first electrode part 31a and the second electrode part 32a, and a gap exists between the first electrode part 31b and the second electrode part 32b. In this regard, the intermediate side of the process chamber 201 is the intermediate side in the arrangement direction (vertical direction) in which the plurality of wafers 200 are arranged. The same applies to the following descriptions. The first electrode parts 31a and 31b and the second electrode parts 32a and 32b are respectively arranged symmetrically with the process chamber 201 interposed therebetween. The first electrode part 31a and the second electrode part 32a are arranged in the vertical direction. The first electrode part 31b and the second electrode part 32b are arranged in the vertical direction. Each of the first electrode parts 31a and 31b and the second electrode parts 32a and 32b is constituted by the electrode unit shown in FIG. 3A. The length of the first-type electrode 300-1 as the first electrode is equal to the length of the zero-type electrode 300-0 as the second electrode.

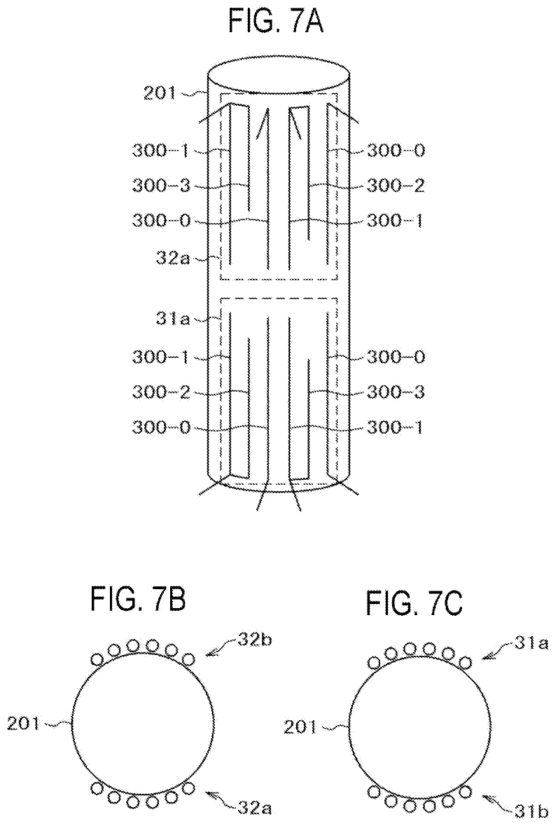

For example, as shown in FIGS. 7A to 7C, the electrode unit includes two first electrode parts 31a and 31b and two second electrode parts 32a and 32b. The first electrode parts 31a and 31b are configured to extend from the lower side to the intermediate side of the process chamber 201. The second electrode parts 32a and 32b are configured to extend from the upper side to the intermediate side of the process chamber 201. At the intermediate side of the process chamber 201, a gap exists between the first electrode part 31a and the second electrode part 32a, and a gap exists between the first electrode part 31b and the second electrode part 32b. The first electrode parts 31a and 31b and the second electrode parts 32a and 32b are respectively arranged symmetrically with the process chamber 201 interposed therebetween. The first electrode part 31a and the second electrode part 32a are arranged in the vertical direction. The first electrode part 31b and the second electrode part 32b are arranged in the vertical direction. Each of the first electrode parts 31a and 31b and the second electrode parts 32a and 32b is constituted by the electrode unit shown in FIG. 4A. Lengths of the first-type electrode 300-1, the second-type electrode 300-2, and the third-type electrode 300-3 included in the first electrodes as the HOT electrodes are different from one another. The length of the first-type electrode 300-1 is the same as the length of the zero-type electrode 300-0 as the second electrode which is the GND electrode. In addition, the length of the second-type electrode 300-2 is shorter than the length of the third-type electrode 300-3.

When the electrode units are arranged as shown in FIGS. 6A to 6C and FIGS. 7A to 7C, one high-frequency power source is used in a case that there is no interference in the upper and lower electrode parts (the second electrode parts 32a and 32b and the first electrode parts 31a and 31b). When considering the interference in the upper and lower electrodes, different (two) high-frequency power sources are used for the upper and lower electrodes to apply high-frequency electric power to the respective electrode parts. At this time, frequencies of the applied high-frequency electric powers may be shifted from each other by about 1 MHz.

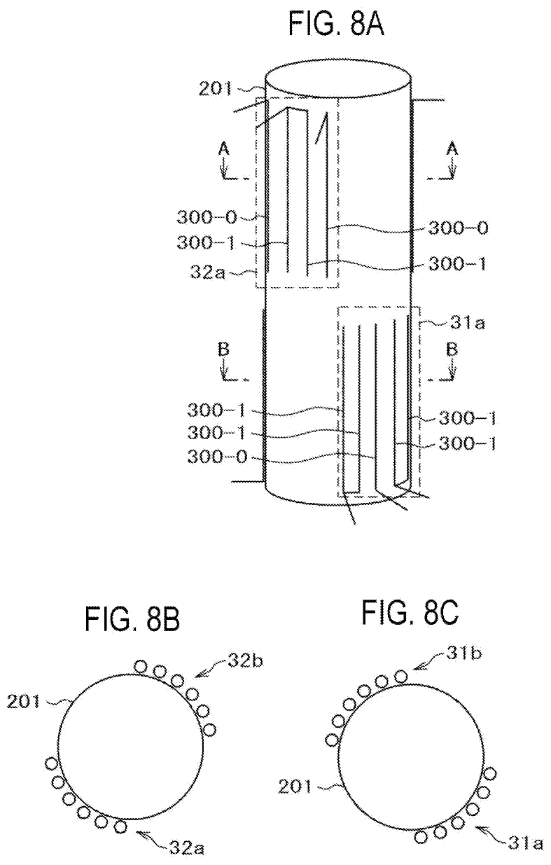

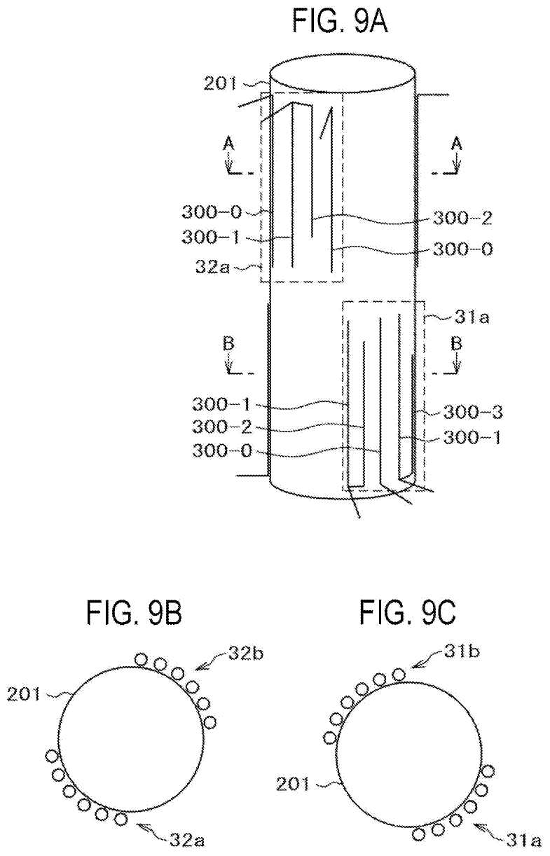

When the same frequency is used in the upper and lower electrode parts, as shown in FIGS. 8A to 8C and FIGS. 9A to 9C, the electrode parts are divided into upper and lower electrode parts at the intermediate side of the process chamber 201, and the arrangement of the upper electrode parts (second electrode parts 32a and 32b) and the arrangement of the lower electrode parts (first electrode parts 31a and 31b) are rotated by 90 degrees (approximately 45 degrees to 90 degrees) in the circumferential direction of the process chamber. By shifting the upper electrode part and the lower electrode part in the circumferential direction in this way, when a distance between the upper electrode part and the lower electrode part increases, the space thus formed performs a function of providing insulation, which makes it possible to prevent the interference.

For example, as shown in FIGS. 8A to 8C, the electrode unit is constituted by two first electrode parts 31a and 31b and two second electrode parts 32a and 32b. The first electrode parts 31a and 31b are configured to extend from the lower side to the intermediate side of the process chamber 201. The second electrode parts 32a and 32b are configured to extend from the upper side to the intermediate side of the process chamber 201. The first electrode parts 31a and 31b and the second electrode parts 32a and 32b are respectively arranged symmetrically with the process chamber 201 interposed therebetween. The first electrode part 31a and the second electrode part 32a are arranged so as to be shifted from each other by 90 degrees in the circumferential direction of the process chamber 201. The first electrode part 31b and the second electrode part 32b are arranged so as to be shifted by 90 degrees in the circumferential direction of the process chamber 201. Each of the first electrode parts 31a and 31b and the second electrode parts 32a and 32b is constituted by the electrode unit shown in FIG. 3A. The length of the first-type electrode 300-1 as the first electrode, which is the HOT electrode is equal to the length of the zero-type electrode 300-0 as the second electrode, which is the GND electrode. Interference may be prevented by arranging the upper second electrode parts 32a and 32b and the lower first electrode parts 31a and 31b to be spaced apart from each other.

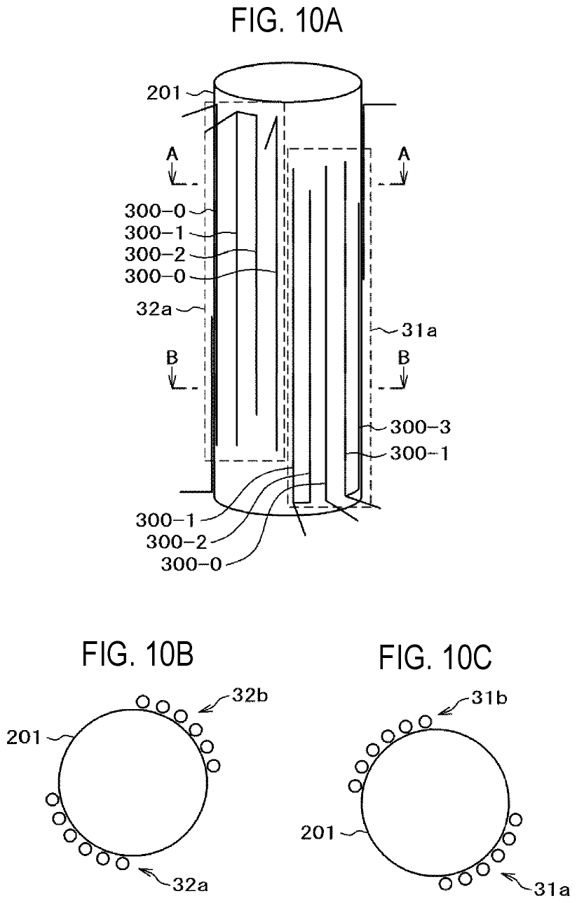

For example, as shown in FIGS. 9A to 9C, the electrode unit is constituted by two first electrode parts 31a and 31b and two second electrode parts 32a and 32b. The first electrode parts 31a and 31b are configured to extend from the lower side to the intermediate side of the process chamber 201. The second electrode parts 32a and 32b are configured to extend from the upper side to the intermediate side of the process chamber 201. The first electrode parts 31a and 31b and the second electrode parts 32a and 32b are respectively arranged symmetrically with the process chamber interposed therebetween. The first electrode part 31a and the second electrode part 32a are arranged so as to be shifted from each other by 90 degrees in the circumferential direction of the process chamber 201. The first electrode part 31b and the second electrode part 32b are arranged so as to be shifted from each other by 90 degrees in the circumferential direction of the process chamber 201. Each of the first electrode parts 31a and 31b and the second electrode parts 32a and 32b is constituted by the electrode unit shown in FIG. 4A. The lengths of the first-type electrode 300-1, the second-type electrode 300-2, and the third-type electrode 300-3 included in the first electrodes as the HOT electrodes, are different from one another. The length of the first-type electrode 300-1 is equal to the length of the zero-type electrode 300-0 as the second electrode, which is the GND electrode. Further, the length of the second-type electrode 300-2 is shorter than the length of the third-type electrode 300-3. Interference may be prevented by arranging the upper second electrode parts 32a and 32b and the lower first electrode parts 31a and 31b to be spaced apart from each other. As shown in FIG. 10A, the first electrode parts 31a and 31b may be configured to extend from the lower side toward upper side over the middle side of the process chamber 201. Further, as shown in FIG. 10A, the second electrode parts 32a and 32b may be configured to extend from the upper side toward the lower side over the middle side of the process chamber 201.

### (Exhauster)

As shown in FIG. 1, an exhaust pipe 231 configured to exhaust an atmosphere inside the process chamber 201 is installed at the reaction tube 203. A vacuum pump 246 as a vacuum exhauster is connected to the exhaust pipe 231 via a pressure sensor 245 as a pressure detector (pressure detection part) configured to detect a pressure inside the process chamber 201 and an APC (Auto Pressure Controller) valve 244 as an exhaust valve (pressure regulator). The APC valve 244 is a valve configured to be capable of performing or stopping vacuum exhaust of the inside of the process chamber 201 by being opened or closed while the vacuum pump 246 is in operation. Further, the APC valve 244 is a valve configured to be capable of regulating the pressure inside the process chamber 201 by adjusting an opening state of the valve based on the pressure information detected by the pressure sensor 245 while the vacuum pump 246 is in operation. An exhaust system mainly includes the exhaust pipe 231, the APC valve 244, and the pressure sensor 245. The vacuum pump 246 may be included in the exhaust system. The exhaust pipe 231 is not limited to being installed at the reaction tube 203, and may be installed at the manifold 209 in the same manner as the nozzles 249a and 249b.

### (Peripheral Apparatus)

Below the manifold 209, a seal cap 219 is installed as a furnace opening lid capable of hermetically closing the lower end opening of the manifold 209. The seal cap 219 is configured to come in contact with the lower end of the manifold 209 from below in the vertical direction. The seal cap 219 is made of, for example, a metal such as stainless steel (SUS) or the like, and is formed in a disc shape. An O-ring 220b as a seal configured to come in contact with the lower end of the manifold 209 is installed on an upper surface of the seal cap 219.

A rotator 267 configured to rotate the boat 217 is installed on the opposite side of the seal cap 219 from the process chamber 201. A rotary shaft 255 of the rotator 267 passes through the seal cap 219 and is connected to the boat 217. The rotator 267 is configured to rotate the wafers 200 by rotating the boat 217. The seal cap 219 is configured to be vertically moved up or down by a boat elevator 115 as an elevator installed vertically outside the reaction tube 203. The boat elevator 115 is configured to be capable of moving the boat 217 into or out of the process chamber 201 by raising or lowering the seal cap 219.

The boat elevator 115 is configured as a transfer apparatus (transfer equipment) configured to transfer the boat 217, i.e., the wafers 200 into or out of the process chamber 201. Further, below the manifold 209, a shutter 219s is installed as a furnace opening lid capable of hermetically closing the lower end opening of the manifold 209 while the seal cap 219 is lowered by the boat elevator 115. The shutter 219s is made of, for example, a metal such as stainless steel (SUS) or the like, and is formed in a disc shape. An O-ring 220c as a seal that comes in contact with the lower end of the manifold 209 is installed on an upper surface of the shutter 219s. The opening/closing operation (elevating operation, rotating operation, etc.) of the shutter 219s is controlled by a shutter opening/closing equipment 115s.

A temperature sensor 263 as a temperature detector is installed inside the reaction tube 203. A state of supplying electric power to the heater 207 is adjusted based on the temperature information detected by the temperature sensor 263, such that a temperature distribution inside the process chamber 201 becomes a desired temperature distribution. A temperature sensor 263 is provided along the inner wall of the reaction tube 203, similar to the nozzles 249a and 249b.

### (Controller)

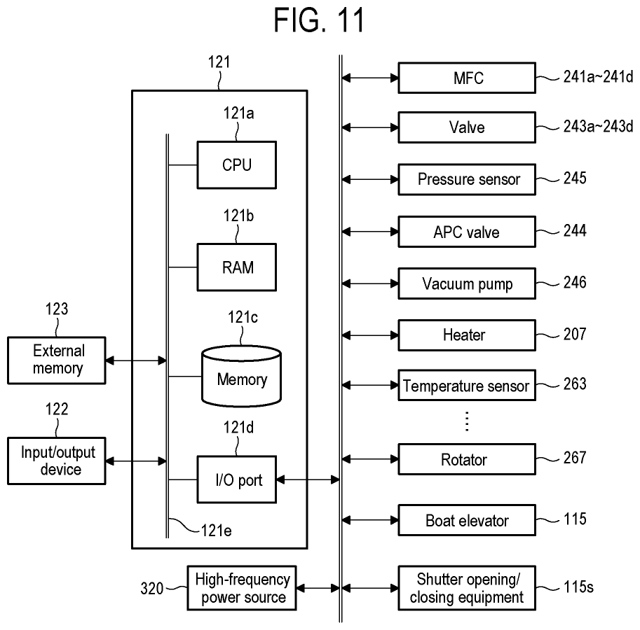

Next, a controller will be explained with reference to FIGS. 11. A controller 121, which is a control part (control apparatus), is configured as a computer including a CPU (Central Processing Unit) 121a, a RAM (Random Access Memory) 121b, a memory 121c, and an I/O port 121d. The RAM 121b, the memory 121c, and I/O port 121d are configured to be capable of exchanging data with the CPU 121a via an internal bus 121e. An input/output device 122 configured as, for example, a touch panel or the like is connected to the controller 121.

The memory 121c includes, for example, a flash memory, a HDD (Hard Disk Drive), a SSD (Solid State Drive), or the like. The memory 121c is configured to readably store a control program that controls the operation of the substrate processing apparatus, a process recipe describing procedures and conditions of a film-forming process described later, and the like. The process recipe is configured to be capable of causing the controller 121 to execute each procedure of various processes (film-forming process), which will be described later, so as to obtain a predetermined result. The process recipe functions as a program. Hereinafter, the process recipe, the control program, and the like will be collectively and simply referred to as program. The process recipe is also simply referred to as a recipe. As used herein, the term program may include the recipe, the control program, or both. The RAM 121b is configured as a memory area (work area) in which the program and data read by the CPU 121a are temporarily held.

The I/O port 121d is connected to the MFCs 241a to 241d, the valves 243a to 243d, the pressure sensor 245, the APC valve 244, the vacuum pump 246, the heater 207, the temperature sensor 263, the rotator 267, the boat elevator 115, and the shutter opening/closing equipment 115s, the high-frequency power source 320, and the like.

The CPU 121a is configured to be capable of reading the control program from the memory 121c and executing the control program, and is configured to be capable of reading recipes from the memory 121c in response to the input of operation commands from the input/output device 122 and the like. The CPU 121a is configured to be capable of, according to the contents of the recipe thus read, controlling the operation of the rotator 267, the flow rate regulation operation for various gases by the MFCs 241a to 241d, the opening/closing operation of the valves 243a to 243d, the opening/closing operation of the APC valve 244, the pressure regulation operation by the APC valve 244 based on the pressure sensor 245, the start and stop of the vacuum pump 246, the temperature regulation operation of the heater 207 based on the temperature sensor 263, the forward/reverse rotation and rotation angle/rotation speed adjustment operation of the boat 217 by the rotator 267, the elevating operation of the boat 217 by the boat elevator 115, the opening/closing operation of the shutter 219s by the shutter opening/closing equipment 115s, the power supply operation of the high-frequency power source 320, and the like.

The controller 121 may be configured by installing, on the computer, the above-described program stored in an external memory (e.g., a magnetic disk such as a hard disk or the like, an optical disc such as a CD or the like, a magneto-optical disc such as a MO or the like, a semiconductor memory such as a USB memory, a SSD or the like, and so forth) 123. The memory 121c and the external memory 123 are configured as computer-readable recording media. Hereinafter, these are also collectively and simply referred to as a recording medium. When the term “recording medium” is used in the present disclosure, it may include the memory 121c, the external memory 123, or both. The program may be provided to the computer by using communication means or unit such as the Internet or a dedicated line instead of using the external memory 123.

### (2) Substrate Processing Process

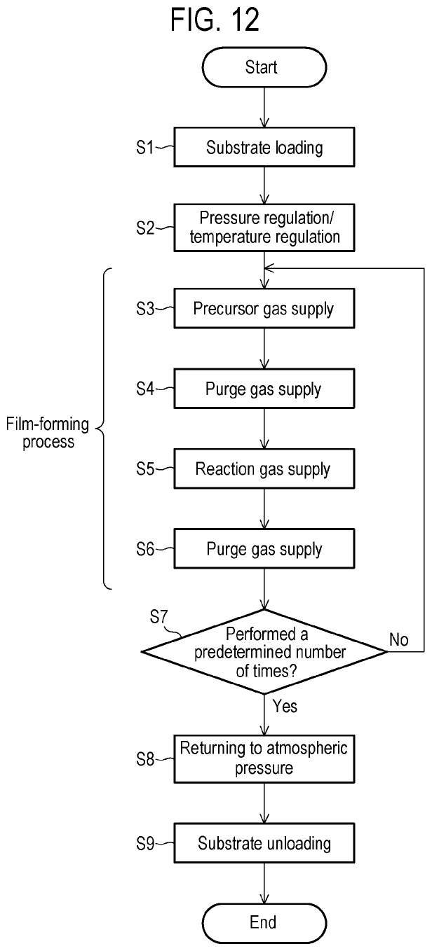

As a process of manufacturing a semiconductor device by using the substrate processing apparatus described above, an example of a process of forming a film on a substrate will be described with reference to FIG. 12. In the following description, an operation of each component of the substrate processing apparatus is controlled by the controller 121.

In the present disclosure, a sequence of a film-forming process shown in FIG. 12 may be denoted as follows for the sake of convenience.

(Precursor Gas→Reactant Gas)×n

The term “wafer” used herein may refer to “a wafer itself” or “a stacked body of a wafer and a predetermined layer or film formed on a surface of a wafer.” The phrase “a surface of a wafer” used herein may refer to “a surface of a wafer itself” or “a surface of a predetermined layer or the like formed on a wafer.” The expression “a predetermined layer is formed on a wafer” used herein may mean that “a predetermined layer is directly formed on a surface of a wafer itself” or that “a predetermined layer is formed on a layer or the like formed on a wafer.” As used herein, the term “substrate” may be synonymous with the term “wafer.”

### (Loading Step: S1)

After a plurality of wafers 200 is charged to the boat 217 (wafer charging), the shutter 219s is moved by the shutter opening/closing equipment 115s to open the lower end opening of the manifold 209 (shutter open). Thereafter, as shown in FIG. 1, the boat 217 supporting the plurality of wafers 200 is lifted by the boat elevator 115 and loaded into the process chamber 201 (boat loading). In such a state, the seal cap 219 seals the lower end of the manifold 209 via the O-ring 220b.

### (Pressure Regulation/Temperature Regulation Step: S2)

The inside of the process chamber 201 is vacuum-exhausted (decompression-exhausted) by the vacuum pump 246 so as to reach a desired pressure (state of vacuum). At this time, the pressure inside the process chamber 201 is measured by the pressure sensor 245, and the APC valve 244 is feedback-controlled based on the measured pressure information (pressure regulation). The vacuum pump 246 is constantly operated at least until the film-forming step, which will be described later, is completed.

Further, the inside of the process chamber 201 is heated by the heater 207 so as to reach a desired temperature. At this time, a state of supplying electrical power to the heater 207 is feedback-controlled based on the temperature information detected by the temperature sensor 263 such that the temperature distribution inside the process chamber 201 becomes a desired temperature distribution (temperature regulation). The heating of the inside of the process chamber 201 by the heater 207 is continued at least until the film-forming step, which will be described later, is completed. However, when the film-forming step is performed under a temperature condition of the room temperature or lower, the heating of the inside of the process chamber 201 by the heater 207 may not be performed. When the processing is performed at such a temperature, the heater 207 may not be used, and the heater 207 may not be installed in the substrate processing apparatus. In such a case, it is possible to simplify a configuration of the substrate processing apparatus.

Subsequently, the rotation of the boat 217 and the wafers 200 by the rotator 267 is started. The rotation of the boat 217 and the wafers 200 by the rotator 267 is continued at least until the film-forming step, which will be described later, is completed.

### (Film-Forming Step: S3, S4, S5, and S6)

Thereafter, the film-forming step is performed by sequentially executing steps S3, S4, S5, and S6.

### (Precursor Gas Supply Steps: S3 and S4)

In step S3, the precursor gas is supplied to the wafers 200 in the process chamber 201.

The valve 243a is opened to allow the precursor gas to flow through the gas supply pipe 232a. A flow rate of the precursor gas is controlled by the MFC 241a. The precursor gas is supplied into the process chamber 201 from the gas supply holes 250a via the nozzle 249a, and is exhausted from the exhaust pipe 231. At this time, the precursor gas is supplied to the wafers 200. At the same time, the valve 243c may be opened to allow the inert gas to flow through the gas supply pipe 232c. A flow rate of the inert gas is controlled by the MFC 241c. The inert gas is supplied into the process chamber 201 together with the precursor gas, and is exhausted from the exhaust pipe 231.

Further, the valve 243d may be opened to allow the inert gas to flow into the gas supply pipe 232d, so as to prevent the precursor gas from entering the nozzle 249b. The inert gas is supplied into the process chamber 201 via the gas supply pipe 232d and the nozzle 249b and is exhausted from the exhaust pipe 231.

A processing condition in this step is exemplified as follows:

Processing temperature: room temperature (25 degrees C.) to 550 degrees C., specifically, 400 to 500 degrees C.

Processing pressure: 1 to 4000 Pa, specifically, 100 to 1000 Pa Supply flow rate of precursor gas: 0.1 to 3 slm Supply time of precursor gas: 1 to 100 seconds, specifically 1 to 50 seconds Supply flow rate of inert gas (for each gas supply pipe): 0 to 10 slm.

In the present disclosure, an expression of a numerical range such as “25 to 550 degrees C.” means that a lower limit and an upper limit are included in that range. Therefore, for example, “25 to 550 degrees C.” means “25 degrees C. or more and 550 degrees C. or less.” The same applies to other numerical ranges. Further, a processing temperature in the present disclosure means a temperature of the wafer 200 or a temperature inside the process chamber 201, and a processing pressure means a pressure inside the process chamber 201. In addition, when a supply flow rate of a gas is 0 slm, it means a case where the gas is not supplied. These also apply to the following descriptions.

By supplying the precursor gas to the wafers 200 under the above-described condition, a first layer is formed on the wafer 200 (on a base film on a surface of the wafer 200). For example, when a silicon (Si)-containing gas, which will be described later, is used as the precursor gas, a Si-containing layer is formed as the first layer.

After the first layer is formed, the valve 243a is closed to stop the supply of the precursor gas into the process chamber 201. At this time, while keeping the APC valve 244 opened, the inside of the process chamber 201 is vacuum-exhausted by the vacuum pump 246, and the unreacted precursor gas, the precursor gas contributed to the formation of the first layer, the reaction by-products, and the like, which remain in the process chamber 201, are removed from the process chamber 201. Further, the valves 243c and 243d are opened to supply the inert gas into the process chamber 201 (S4). The inert gas acts as a purge gas.

Examples of the precursor gas may include aminosilane-based gases such as a tetrakis(dimethylamino)silane (Si[N(CH₃)₂]₄, abbreviation: 4DMAS) gas, a tris(dimethylamino)silane (Si[N(CH₃)₂]₃H, abbreviation: 3DMAS) gas, a bis(dimethyl amino)silane (Si[N(CH₃)₂]₂H₂, abbreviation: BDMAS) gas, a bis(diethylamino)silane (Si[N(C₂H₅)₂]₂H₂, abbreviation: BDEAS) gas, a bis(tert-butyl)aminosilane (SiH₂[NH(C₄H₉)]₂, abbreviation: BTBAS) gas, a (diisopropylamino)silane (SiH₃[N(C₃H₇)₂], abbreviation: DIPAS) gas, and the like. One or more selected from the group of these gases may be used as the precursor gas.

Examples of the precursor gas may include: chlorosilane-based gases such as a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, an octachlorotrisilane (Si₃Cl₈, abbreviation: OCTS) gas, and the like; fluorosilane-based gases such as a tetrafluorosilane (SiF₄) gas, a difluorosilane (SiH₂F₂) gas, and the like; bromosilane-based gases such as a tetrabromosilane (SiBr₄) gas, a dibromosilane (SiH₂Br₂) gas, and the like; and iodosilane-based gases such as a tetraiodosilane (SiI₄) gas, a diiodosilane (SiH₂I₂) gas, and the like. That is, a halosilane-based gas may be used as the precursor gas. One or more selected from the group of these gases may be used as the precursor gas.

Further, as the precursor gas, for example, silicon hydride gases such as a monosilane (SiH₄, abbreviation: MS) gas, a disilane (Si₂H₆, abbreviation: DS) gas, a trisilane (Si₃H₈, abbreviation: TS) gas, and the like may be used. One or more selected from the group of these gases may be used as the precursor gas.

As the inert gas, for example, a nitrogen (N₂) gas, or rare gases such as an argon (Ar) gas, a helium (He) gas, a neon (Ne) gas, a xenon (Xe) gas and the like may be used. One or more selected from the group of these gases may be used as the inert gas. This point also applies to each step described later.

### (Reaction Gas Supply Step: S5 and S6)

After the precursor gas supply step is completed, a plasma-excited reaction gas is supplied to the wafers 200 in the process chamber 201 (S5).

In this step, the opening/closing control of the valves 243b to 243d is performed in the same procedure as the opening/closing control of the valves 243a, 243c, and 243d in step S3. A flow rate of the reaction gas is regulated by the MFC 241b. The reaction gas is supplied into the process chamber 201 from the gas supply holes 250b via the nozzle 249b. At this time, high-frequency electric power (RF power) is supplied (applied) from the high-frequency power source 320 to the electrodes 300. The reaction gas supplied into the process chamber 201 is excited into a plasma state inside the process chamber 201, is supplied as active species to the wafers 200, and is exhausted from the exhaust pipe 231.

A processing condition in this step is exemplified as follows:

Processing temperature: room temperature (25 degrees C.) to 550 degrees C., specifically 400 to 500 degrees C.

Processing pressure: 1 to 300 Pa, specifically 10 to 100 Pa Supply flow rate of reaction gas: 0.1 to 10 slm Supply time of reaction gas: 1 to 100 seconds, specifically 1 to 50 seconds Supply flow rate of inert gas (for each gas supply pipe): 0 to 10 slm RF power: 50 to 1000 W RF frequency: 27.12 MHz.

By supplying the reaction gas in a plasma state to the wafers 200 under the above-described condition, the first layer formed on the surface of the wafer 200 is subjected to a modification process by action of ions and electrically neutral active species generated in the plasma, whereby the first layer is modified into a second layer.

For example, when an oxidizing gas (oxidizing agent) such as an oxygen (O)-containing gas or the like is used as the reaction gas, O-containing active species are generated by exciting the O-containing gas into a plasma state. The O-containing active species are supplied to the wafers 200. In such a case, the first layer formed on the surface of the wafer 200 is subjected to an oxidizing process as a modification process by the action of the O-containing active species. In this case, in a case where the first layer is, for example, a Si-containing layer, the Si-containing layer as the first layer is modified into a silicon oxide layer (SiO layer) as a second layer.

Further, when a nitriding gas (nitriding agent) such as a nitrogen (N)- and hydrogen (H)-containing gas is used as the reaction gas, N- and H-containing gas species are generated by exciting the N- and H-containing gas into a plasma state. The N- and H-containing active species are supplied to the wafers 200. In this case, the first layer formed on the surface of the wafer 200 is subjected to nitriding treatment as a modification treatment by the action of N- and H-containing active species. In this case, in a case where the first layer is, for example, a Si-containing layer, the Si-containing layer as the first layer is modified into a silicon nitride layer (SiN layer) as a second layer.

After modifying the first layer into the second layer, the valve 243b is closed to stop the supply of the reaction gas. Further, the supply of the RF power to the electrodes 300 is stopped. Then, the reaction gas, reaction by-products, and the like remaining in the process chamber 201 are removed from the process chamber 201 by the same processing procedure and processing condition as in step S4. Further, the valves 243c and 243d are opened to supply the inert gas into the process chamber 201 (S6). The inert gas acts as a purge gas.

As the reaction gas, for example, the O-containing gas or the N- and H-containing gas may be used as described above. As the O-containing gas, for example, an oxygen (O₂) gas, a nitrous oxide (N₂O) gas, a nitric oxide (NO) gas, a nitrogen dioxide (NO₂) gas, an ozone (O₃) gas, a hydrogen peroxide (H₂O₂) gas, a water vapor (H₂O), an ammonium hydroxide (NH₄(OH)) gas, a carbon monoxide (CO) gas, a carbon dioxide (CO₂) gas, and the like may be used. As the N- and H-containing gas, for example, a hydrogen nitride-based gas such as an ammonia (NH₃) gas, a diazene (N₂H₂) gas, a hydrazine (N₂H₄) gas, a N₃H₈ gas, or the like may be used. One or more selected from the group of these gases may be used as the reaction gas.

As the inert gas, for example, various gases exemplified in step S4 may be used.

### (Performing a Predetermined Number of Times: S7)

A cycle in which the steps S3, S4, S5, and S6 described above are performed in the named order non-simultaneously, i.e., without synchronization, may be performed a predetermined number of times (n times where n is an integer of 1 or more), i.e., one or more times, to form a film with a predetermined composition and a predetermined thickness on the wafer 200. The above-described cycle may be performed multiple times. That is, a thickness of the second layer formed per cycle is set to be smaller than a desired film thickness, and the cycle may be performed multiple times until a thickness of a film formed by laminating the second layer reaches the desired film thickness. In a case where, for example, a Si-containing layer is formed as the first layer and, for example, a SiO layer is formed as the second layer, a silicon oxide film (SiO film) is formed as the film. Further, in a case where, for example, a Si-containing layer is formed as the first layer and, for example, a SiN layer is formed as the second layer, a silicon nitride film (SiN film) is formed as the film.

### (Returning to Atmospheric Pressure Step: S8)

After the film-forming process described above is completed, the inert gas is supplied into the process chamber 201 via the gas supply pipes 232c and 232d, and is exhausted from the exhaust pipe 231. As a result, the inside of the process chamber 201 is purged with the inert gas, and the reaction gas and the like remaining in the process chamber 201 are removed from the inside of the process chamber 201 (inert gas purge). Thereafter, the atmosphere in the process chamber 201 is replaced with the inert gas (inert gas replacement), and the pressure inside the process chamber 201 is returned to the atmospheric pressure (returning to atmospheric pressure restoration: S8).

### (Unloading Step: S9)

Thereafter, the seal cap 219 is lowered by the boat elevator 115 to open the lower end of the manifold 209, and the processed wafers 200 are unloaded to the outside of the reaction tube 203 from the lower end of the manifold 209 while being supported by the boat 217 (boat unloading). After the boat is unloaded, the shutter 219s is moved and the lower end opening of the manifold 209 is sealed by the shutter 219s via the O-ring 220c (shutter closing). The processed wafers 200 are unloaded from the reaction tube 203 and are then discharged from the boat 217 (wafer discharging). An empty boat 217 may be loaded into the process chamber 201 after the wafer discharging.

In this case, the pressure inside the process furnace during substrate processing may be controlled to fall within a range of 10 Pa or more and 300 Pa or less. This is because when the pressure inside the process furnace is lower than 10 Pa, the mean free path of the gas molecule becomes longer than the Debye length of the plasma, and the plasma that directly hits the furnace wall becomes conspicuous, which makes it difficult to suppress the generation of particles. Further, when the pressure inside the process furnace is higher than 300 Pa, the plasma generation efficiency is saturated. Therefore, even when the reaction gas is supplied, the amount of plasma generated is not changed, the reaction gas is wasted and the mean free path of the gas molecule is shortened. Thus, an efficiency of transport of plasma active species to the wafer deteriorates.

### (3) Effects of the Embodiments of the Present Disclosure

By dividing and arranging the electrode units in the longitudinal direction, the electric field generated between the inner wall of the reaction tube 203 near the electrodes 300 and the wafers 200 is uniformly and strongly distributed in the vertical direction (the direction in which the substrates are stacked). This allows the plasma 302 to be dense and uniformly distributed in the vertical direction, which makes it possible to simultaneously increase efficiency and quality of substrate processing and inter-substrate uniformity. In addition, since a power supply of a higher frequency may be used, it is possible to achieve at least one selected from the group of ion damage reduction, low electron temperature, and high plasma density.

The embodiments of the present disclosure are specifically described above. However, the present disclosure is not limited to the above-described embodiments, and various modifications may be made without departing from the gist of the present disclosure.

Further, for example, in the above-described embodiments, the example in which the reactant is supplied after supplying the precursor is described. The present disclosure is not limited to such an embodiment. The supply order of the precursor and the reactant may be reversed. That is, the precursor may be supplied after supplying the reactant. By changing the supply order, it is possible to change film quality and composition ratio of a film to be formed.

The present disclosure may be suitably applied to a case of forming a Si-based oxide film such as a silicon oxycarbide film (SiOC film), a silicon oxycarbonitride film (SiOCN film), a silicon oxynitride film (SiON film), or the like on the wafer 200, as well as the case of forming the SiO film or the SiN film on the wafer 200.

For example, in place of the above-described gases, or in addition to the above-described gases, a nitrogen (N)-containing gas such as an ammonia (NH₃) gas or the like, a carbon (C)-containing gas such as a propylene (C₃H₆) gas or the like, and a boron (B)-containing gas such as a boron trichloride (BCl₃) gas or the like may be used to form a film. For example, a SiN film, a SiON film, a SiOCN film, a SiOC film, a SiCN film, a SiBN film, a SiBCN film, a BCN film, and the like may be formed. Further, an order in which the respective gases are supplied may be changed as appropriate. Even when such film formations are performed, the films may be formed under the same processing conditions as those in the above-described embodiments, and the same effects as those in the above-described embodiments may be obtained. In these cases, the reaction gas described above may be used as the oxidizing agent which is the reaction gas.

The present disclosure may also be suitably applied to a case of forming, on the wafer 200, a metal-based oxide film or a metal-based nitride film containing a metal element such as titanium (Ti), zirconium (Zr), hafnium (Hf), tantalum (Ta), niobium (Nb), aluminum (Al), molybdenum (Mo), tungsten (W), or the like. That is, the present disclosure may also be suitably applied to a case of forming, on the wafer 200, a TiO film, a TiOC film, a TiOCN film, a TiON film, a TiN film, a TiSiN film, a TiBN film, a TiBCN film, a ZrO film, a ZrOC film, a ZrOCN film, a ZrON film, a ZrN film, a ZrSiN film, a ZrBN film, a ZrBCN film, a HfO film, a HfOC film, a HfOCN film, a HfON film, a HfN film, a HfSiN film, a HfBN film, a HfBCN film, a TaO film, a TaOC film, a TaOCN film, a TaON film, a TaN film, a TaSiN film, a TaBN film, a TaBCN film, a NbO film, a NbOC film, a NbOCN film, a NbON film, a NbN film, a NbSiN film, a NbBN film, a NbBCN film, an AlO film, an AlOC film, an AlOCN film, an AlON film, an AN film, an AlSiN film, an AlBN film, an AlBCN film, a MoO film, a MoOC film, a MoOCN film, a MoON film, a MoN film, a MoSiN film, a MoBN film, a MoBCN film, a WO film, a WOC film, a WOCN film, a WON film, a WN film, a WSiN film, a WBN film, a WBCN film, and the like.

In these cases, as the precursor gas, for example, a tetrakis(dimethylamino)titanium (Ti[N(CH₃)₂]₄, abbreviation: TDMAT) gas, a tetrakis(ethylmethylamino)hafnium (Hf[N(C₂H₅)(CH₃)]₄, abbreviation: TEMAH) gas, a tetrakis(ethylmethylamino)zirconium (Zr[N(C₂H₅)(CH₃)]₄, abbreviation: TEMAZ) gas, a trimethylaluminum (Al(CH₃)₃, abbreviation: TMA) gas, a titanium tetrachloride (TiCl₄) gas, a hafnium tetrachloride (HfCl₄) gas, or the like may be used.

That is, the present disclosure may be suitably applied to a case of forming a semi-metal-based film containing a semi-metal element or a metal-based film containing a metal element. The processing procedures and processing conditions of these film-forming processes may be the same as those of the film-forming processes shown in the above-described embodiments. Even in these cases, the same effects as those of the above-described embodiments may be obtained.

Recipes used in the film-forming process may be individually provided according to process contents and stored in the memory 121c via the electric communication line or the external memory 123. Then, when starting various kinds of processing, the CPU 121a may appropriately select an appropriate recipe from among a plurality of recipes stored in the memory 121c according to the process contents. As a result, thin films of various types, composition ratios, film qualities, and film thicknesses may be formed universally with good reproducibility by using a single substrate processing apparatus. In addition, burden on an operator may be reduced, and various processes may be started quickly while avoiding operational errors.

The above-described recipes are not limited to being newly created, but may be provided, for example, by changing an existing recipe already installed in the substrate processing apparatus. When changing the recipe, the changed recipe may be installed in the substrate processing apparatus via an electric communication line or a recording medium that records the recipe. Alternatively, an existing recipe already installed in the substrate processing apparatus may be directly changed by operating the input/output device 122 included in the existing substrate processing apparatus.

According to the present disclosure in some embodiments, it is possible to uniformly process a film formed on a substrate.

While certain embodiments are described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process chamber configured to process a plurality of substrates; and
a plasma generator configured to generate plasma in the process chamber, the plasma generator including a first electrode part configured to extend from a lower side to an intermediate side of the process chamber, and a second electrode part configured to extend from an upper side to the intermediate side of the process chamber.

2. The substrate processing apparatus of claim 1, wherein the plasma generator includes a gap between the first electrode part and the second electrode part at the intermediate side of the process chamber.

3. The substrate processing apparatus of claim 1, wherein each of the first electrode part and the second electrode part includes at least one first electrode to which an arbitrary potential is applied and at least one second electrode to which a reference potential is applied.

4. The substrate processing apparatus of claim 3, wherein the at least one first electrode includes a plurality of first electrodes to which the arbitrary potential is applied.

5. The substrate processing apparatus of claim 4, wherein lengths of the plurality of first electrodes are the same.

6. The substrate processing apparatus of claim 4, wherein lengths of the plurality of first electrodes are the same as a length of the at least one second electrode.

7. The substrate processing apparatus of claim 4, wherein lengths of the plurality of first electrodes are different.

8. The substrate processing apparatus of claim 7, wherein a length of a longer one of the plurality of first electrodes is the same as a length of the at least one second electrode.

9. The substrate processing apparatus of claim 4, wherein the plurality of first electrodes include two first electrodes,
wherein the at least one second electrode includes one second electrode, and
wherein each of the first electrode part and the second electrode part includes the two first electrodes and the one second electrode, which are arranged in an order of the first electrode, the first electrode, and the second electrode.

10. The substrate processing apparatus of claim 3, wherein each of the first electrode part and the second electrode part includes a cover configured to hold the at least one first electrode and the at least one second electrode.

11. The substrate processing apparatus of claim 1, wherein the first electrode part and the second electrode part are arranged at positions shifted in a circumferential direction of the process chamber.

12. The substrate processing apparatus of claim 1, wherein the first electrode part and the second electrode part are installed outside the process chamber.

13. The substrate processing apparatus of claim 1, wherein the substrate processing apparatus further comprises a heater configured to heat the substrates, and
wherein the first electrode part and the second electrode part are installed between the process chamber and the heater.

14. The substrate processing apparatus of claim 3, wherein the at least one first electrode and the at least one second electrode are plate-shaped.

15. The substrate processing apparatus of claim 1, wherein the intermediate side is an intermediate side of the process chamber in an arrangement direction in which the plurality of substrates are arranged.

16. The substrate processing apparatus of claim 1, further comprising a gas supplier configured to supply a processing gas to the plurality of substrates.

17. A plasma generation apparatus, comprising:
a first electrode part configured to extend from a lower side to an intermediate side of a process chamber; and
a second electrode part configured to extend from an upper side to the intermediate side of the process chamber.

18. A method of processing a substrate, comprising:
loading a substrate into a process chamber; and
generating plasma in the process chamber by a first electrode part configured to extend from a lower side to an intermediate side of the process chamber and a second electrode part configured to extend from an upper side to the intermediate side of the process chamber.

19. A method of manufacturing a semiconductor device, comprising the method of claim 18.

20. A non-transitory computer-readable recording medium storing a program that causes, by a computer, a substrate processing apparatus to perform a process comprising the method of claim 18.
